(19) United States
(12) Patent Application Publication
(10) Pub. No.: US 2010/0131749 A1
(43) Pub. Date: May 27, 2010

(54) APPARATUS AND METHOD FOR CONTROLLING OPERATING MODE OF MOBILE TERMINAL

(75) Inventors: Kyung Hwa Kim, Seoul (KR); Jung Yeob Oh, Seongnam-si (KR); Myeong Lo Lee, Seoul (KR); Seung Woo Shin, Seoul (KR); Jin Yong Kim, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD, Suwon-si (KR)

(21) Appl. No.: 12/625,966

(22) Filed: Nov. 25, 2009

(30) Foreign Application Priority Data
Nov. 27, 2008 (KR) 10-2008-0119052

(51) Int. Cl. G06F 9/00; H03G 3/00

(52) U.S. Cl. 713/100; 381/107

(57) ABSTRACT

An operating mode control apparatus and method for a mobile terminal are disclosed. The apparatus and method enable the user to control the operation of a mobile terminal on the basis of the proximity of the user to the mobile terminal, the movement of the mobile terminal, and the housing orientation thereof. Hence, the user may enjoy a visuo-spatial user interface.

### CROSS REFERENCE TO RELATED APPLICATION

This application claims priority from and the benefit of Korean Patent Application No. 10-2008-0119052, filed on Nov. 27, 2008, which is hereby incorporated by reference for all purposes as if fully set forth herein.

### BACKGROUND OF THE INVENTION

1. Field of the Invention

Exemplary embodiments of the present invention relate generally to a mobile terminal and, more particularly, to an apparatus and method that controls the operating mode of a mobile terminal through sensing proximity between the mobile terminal and the user, and sensing motion of the mobile terminal.

2. Discussion of the Background

Mobile terminals have become a necessity of life. To satisfy diversified user requirements, mobile terminals having advanced features in terms of design, function and efficiency have been developed. In particular, user interfaces that enable users to manipulate mobile terminals in an intuitive and convenient manner have attracted great attention. To build such user interfaces, techniques enhancing user convenience have been continuously developed through employing new input means or through combining new input means with existing input means.

Regular user interfaces tend to employ hardware keypads. Modern user interfaces use touch pads or touch screens as input means for flexible and fast manipulation of mobile terminals.

To generate a desired input signal in an existing user interface, however, the user may have to view the key pad or the touch screen and precisely press a specific key button or precisely touch a specific zone of the touch screen. That is, for accurate input in the existing user interface, the user may have to suspend the ongoing work or operation and actually view the input process. This may cause interruption of the ongoing work and cause inconvenience to the user.

### SUMMARY OF THE INVENTION

Exemplary embodiments of the present invention provide an apparatus and method that enable the user to control the operating mode of a mobile terminal by moving the mobile terminal.

Exemplary embodiments of the present invention also provide an apparatus and method that control the operating mode of a mobile terminal on the basis of the proximity between the user and mobile terminal, and motion of the mobile terminal.

Additional features of the invention will be set forth in the description which follows, and in part will be apparent from the description, or may be learned by practice of the invention.

An exemplary embodiment of the present invention discloses an operating mode control apparatus for a mobile terminal, including a sensor unit to sense a proximity of a user to the mobile terminal, to sense a housing orientation of the mobile terminal, and to output a sensing signal that indicates at least one of the proximity and the housing orientation, a storage unit to store operating mode information of the mobile terminal corresponding to the sensing signal from the sensor unit, and a control unit to receive the sensing signal and to control an operating mode of the mobile terminal on the basis of the operating mode information corresponding to the received sensing signal.

An exemplary embodiment of the present invention also discloses an operating mode control method for a mobile terminal, including sensing a proximity of a user to the mobile terminal, and sensing a housing orientation of the mobile terminal, and controlling an operating mode of the mobile terminal on the basis of a sensing signal and operating mode information corresponding to the sensing signal, the sensing signal indicating at least one of the proximity and the housing orientation.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a block diagram of a mobile terminal according to an exemplary embodiment of the present invention.

FIG. 2 illustrates a detailed view of a control unit of the mobile terminal.

FIG. 3 is a flow chart illustrating an operating mode control method according to another exemplary embodiment of the present invention.

FIG. 4 is a flow chart of a procedure for operation control in the regular conversation mode.

FIG. 5 is a flow chart of a procedure for operation control in the idle mode.

FIG. 6 is a flow chart of a procedure for operation control during execution of an application.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

Detailed descriptions of well-known functions and structures incorporated herein may be omitted to avoid obscuring the subject matter of the present invention. Particular terms may be defined to describe the invention in the best manner. Accordingly, the meaning of specific terms or words used in the specification and the claims should not be limited to the literal or commonly employed sense, but should be construed in accordance with the spirit of the invention. The description of the various exemplary embodiments is to be construed as exemplary only and does not describe every possible instance of the invention. Therefore, it should be understood that various changes may be made and equivalents may be substituted for elements of the invention.

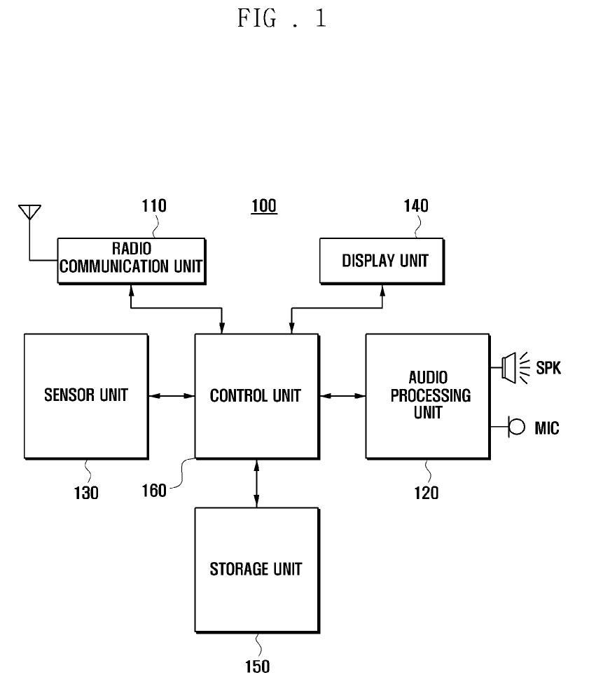

FIG. 1 is a block diagram of a mobile terminal 100 according to an exemplary embodiment of the present invention.

Referring to FIG. 1, the mobile terminal 100 includes a radio communication unit 110, an audio processing unit 120, a sensor unit 130, a display unit 140, a storage unit 150, and a control unit 160.

Under the control of the control unit 160, the radio communication unit 110 sends and receives voice signals for calls and sends and receives data signals for data communication. The radio communication unit 110 may include a radio frequency (RF) transmitter for upconverting the frequency of a signal to be transmitted and amplifying the signal, and an RF receiver for low-noise amplifying a received signal and downconverting the frequency of the received signal. Under the control of the control unit 160, the radio communication unit 110 establishes a communication channel for voice and data communication with an external communication device, and sends and receives voice signals, video signals, short text messages, and multimedia messages through the communication channel.

The audio processing unit 120 may include a coder/decoder (codec). The codec may have a data codec for processing packet data and the like, and an audio codec for processing an audio signal such as a voice signal. The audio processing unit 120 converts a digital audio signal into an analog audio signal through the audio codec and reproduces the analog audio signal through a speaker SPK, and converts an analog audio signal from a microphone MIC into a digital audio signal through the audio codec. In particular, the audio processing unit 120 may adjust the path toward or gain of the speaker SPK on the basis of a sensing signal from the sensor unit 130. In addition to the speaker SPK, the audio processing unit 120 may adjust the gain of the microphone MIC. For example, when the mobile terminal 100 is equipped with two or more speakers having different gains, paths leading to the speakers may be changed for sound output control according to a sensing signal from the sensor unit 130. When the mobile terminal 100 is equipped with a speaker having a variable gain, the gain of the speaker may be adjusted for sound output control according to a sensing signal from the sensor unit 130.

The sensor unit 130 is driven by power supplied under the control of the control unit 160. The sensor unit 130 senses contact (i.e., physical touching) between the user and mobile terminal 100, the orientation of the housing of the mobile terminal 100 and the like, and outputs a corresponding sensing signal to the control unit 160. Such sensing signal may include, for example, operation mode information of the mobile terminal 100. The sensor unit 130 includes a first sensor unit to sense the contact between the user and mobile terminal 100 and a second sensor unit to sense the housing orientation thereof. For example, the first sensor unit may include a proximity sensor, infrared sensor, ambient light sensor, touch sensor, pressure sensor, and/or temperature sensor, and the second sensor unit may include an acceleration sensor, gyro sensor, geomagnetic sensor, and/or image sensor. The sensor unit 130 may also sense movement of the mobile terminal 100 through a separate sensor or the second sensor unit. The sensors noted above in the first sensor unit and second sensor unit are illustrative only, and any other sensors that are capable of sensing a contact, orientation, and/or movement may be employed.

The display unit 140 is installed in the housing of the mobile terminal 100, and displays a screen associated with an activated function. For example, the display unit 140 may display a boot screen, idle screen, menu screen, and/or call handling screen. The display unit 140 may include, for example, a panel of liquid crystal display (LCD) devices or organic light emitting diodes (OLED), a display controller, and/or a memory to store data. When the display unit 140 has a touch screen capability based on a touch sensor, the display unit 140 may also act as an input means for input of, for example, characters, numbers, various touch events, and sweeping actions to the mobile terminal 100.

The storage unit 150 stores programs for controlling the operation of the mobile terminal 100, and data generated from execution of the programs. The storage unit 150 provides a buffer to temporarily store sensing signals from the sensor unit 130, and stores control information for controlling the speaker SPK, microphone MIC, and display unit 140 according to the contact sensed between the user and mobile terminal 100, movement of the mobile terminal 100, and housing orientation thereof. The storage unit 150 may include a program area and a data area.

The program area stores the operating system for booting the mobile terminal 100, application programs for supporting the sensor unit 130, and application programs for supplementary functions such as, for example, playback of sounds, images and moving images. In particular, the program area may store application programs to operate individual sensors of the sensor unit 130.

The data area stores data generated from the use of the mobile terminal 100. For example, the data area stores user data related to various supplementary functions such as, for example, moving images, phonebook data, audio data, digital content, and metadata. The data area may also store control information for controlling the speaker SPK, microphone MIC, and display unit 140 according to the contact sensed between the user and mobile terminal 100, movement of the mobile terminal 100, and housing orientation thereof. The data area may store mappings between application states and elements of the control information for the speaker SPK, microphone MIC, and display unit 140.

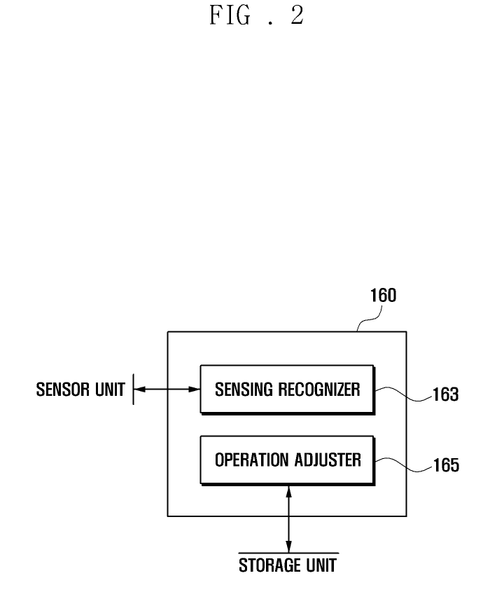

The control unit 160 controls the overall operation of the mobile terminal 100. The control unit 160 also controls data transmission and reception. The control unit 160 controls the path toward the speaker SPK, the gain of the speaker SPK or microphone MIC, and turning on and off of the display unit 140 according to the contact sensed between the user and mobile terminal 100, movement of the mobile terminal 100, and housing orientation thereof. To achieve this, the control unit 160 may include a sensing recognizer 163 and an operation adjuster 165, as shown in FIG. 2.

The sensing recognizer 163 determines the proximity of the user to the mobile terminal 100, the movement of the mobile terminal 100, and the housing orientation thereof on the basis of a sensing signal from the sensor unit 130. That is, the sensing recognizer 163 determines whether a user contacts a zone of the mobile terminal 100 on the basis of a sensing signal from the first sensor unit. If the user is not contacting the zone of the mobile terminal 100, the sensing recognizer 163 outputs an activation signal to the second sensor unit and determines the housing orientation of the mobile terminal 100 on the basis of a sensing signal from the second sensor unit. Here, the housing orientation refers to the orientation of the side of the mobile terminal 100 on which the display unit 140 is installed, relative to the ground. The sensing recognizer 163 identifies movement of the mobile terminal 100 on the basis of a motion sensing signal from the sensor unit 130. The sensing recognizer 163 may identify, for example, shaking movement of the mobile terminal 100 due to an applied force with a specific orientation, angle, and period.

The operation adjuster 165 reads control information for the speaker SPK, microphone MIC, and display unit 140 from the storage unit 150, and controls the operating mode of the mobile terminal 100, according to the identification result from the sensing recognizer 163, by, for example, controlling the path toward the speaker SPK, controlling the gain of the speaker SPK or microphone MIC, and turning on and off of the display unit 140.

Next, a description is given of an operating mode control method for the mobile terminal.

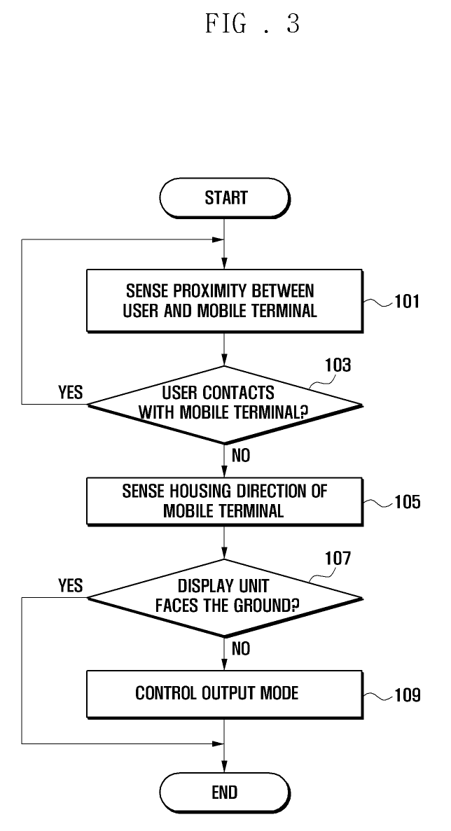

FIG. 3 is a flow chart illustrating an operating mode control method according to another exemplary embodiment of the present invention.

Referring to FIG. 3, in operation 101, when an event occurs in the mobile terminal 100 or an event is handled by the mobile terminal 100, the sensor unit 130 senses the proximity of the user to the mobile terminal 100. Here, the sensor unit 130 is preferably installed at a zone of the mobile terminal 100 that is easily contacted by the hand or ear. For example, a proximity sensor, infrared sensor, ambient light sensor, touch sensor, pressure sensor, or temperature sensor may be installed near the speaker or display unit, which is brought into contact with the ear or the face during a call. The event may correspond to, for example, reception of a call, placement of a call, activation or deactivation of an application such as a music player or digital multimedia broadcasting (DMB) receiver. The event may also correspond to, for example, activation or deactivation of the speaker SPK of the mobile terminal. Handling of various events is described in detail later.

In operation 103, the control unit 160 checks whether the user contacts the mobile terminal 100. If the user does not contact the mobile terminal 100, in operation 105 the control unit 160 controls the sensor unit 130 to sense the housing orientation of the mobile terminal 100. When the sensor sensing the proximity is different from that sensing the housing orientation, it is preferable to activate the sensor sensing the housing orientation after determining that the user is not contacting the mobile terminal 100. When the sensor for sensing the housing orientation or movement of the mobile terminal 100 (such as, for example, an acceleration sensor, gyro sensor, geomagnetic sensor, or image sensor) is always activated in the sensing state, power consumption of the mobile terminal 100 increases and the possibility of malfunction as to other movements also increases. Hence, it is preferable to set activation times for individual sensors. The sensor unit 130 may also sense movement of the mobile terminal 100.

In operation 107, the control unit 160 determines whether the display unit 140 faces the ground on the basis of the sensing result from the sensor unit 130. Here, it is assumed that the ‘front’ of the mobile terminal 100 refers to the side on which the display unit 140 is situated in the housing of the mobile terminal 100, and the ‘back’ of the mobile terminal 100 refers to the opposite side. That is, when the front of the mobile terminal 100 faces away from the ground, the back thereof faces the ground; and when the front of the mobile terminal 100 faces the ground, the back thereof faces away from the ground.

If the front of the mobile terminal 100 does not face the ground, in operation 109 the control unit 160 controls the operating mode by changing the path toward the speaker SPK or adjusting the gain of the speaker SPK. This serves to enable the user at a short distance from the mobile terminal 100 to hear sounds from the speaker SPK. In addition to the speaker SPK, the gain of the microphone MIC may be adjusted according to the state of the mobile terminal 100. For example, when the user holds or places the mobile terminal 100 a short distance from the ear during a phone conversation with a counterpart while the front of the mobile terminal 100 does not face the ground, the control unit 160 may transition to speakerphone mode by controlling the speaker SPK so that the volume of the voice from the counterpart is raised and by adjusting the gain of the microphone MIC so that the voice of the user is readily received.

In addition to the housing orientation, movement of the mobile terminal 100 may be considered for operating mode control. That is, when a sensed movement value is less than or equal to a threshold value and the front of the mobile terminal 100 does not face the ground, the control unit 160 may control the operating mode of the mobile terminal 100. The threshold value is preferably set to zero, and may be set to another value provided that the mobile terminal 100 does not malfunction owing to the adjusted threshold value.

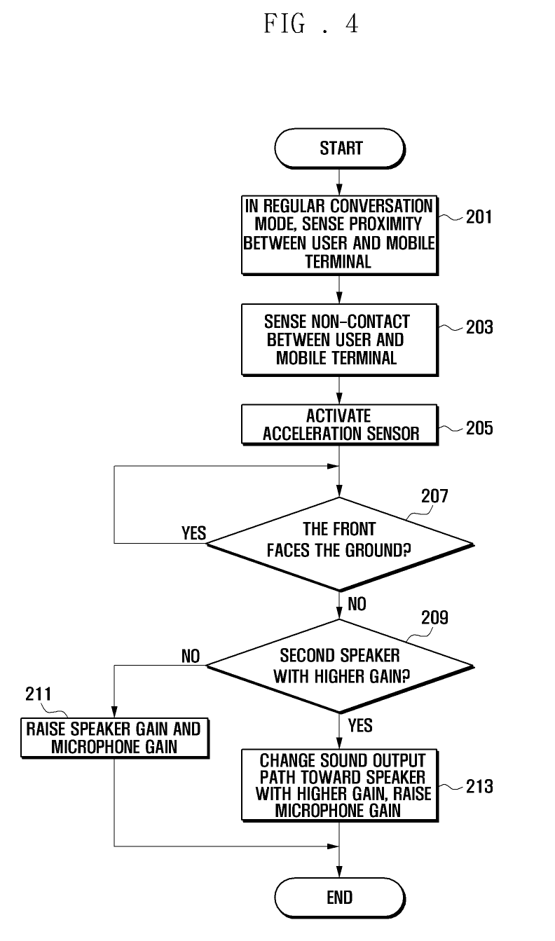

Next, a description is given of a procedure for transitioning from the regular conversation mode to the speakerphone mode in connection with FIG. 4. Here, the regular conversation mode refers to the case where the user is engaged in a phone conversation while the speaker zone of the mobile terminal 100 is in contact with the ear. The speakerphone mode refers to the case where the speaker volume is raised and the microphone gain is heightened so that the user can have a phone conversation at a short distance from the mobile terminal 100.

Referring to FIG. 4, in operation 201, when the mobile terminal 100 enters into the regular conversation mode, the control unit 160 controls the proximity sensor to sense the proximity of the user to the mobile terminal 100. Here, the proximity sensor may be any sensor that can sense contact or non-contact. The proximity sensor may be installed near the speaker SPK or at the display unit 140 so that it can be brought into contact with the ear or the face during a call.

When the proximity sensor senses non-contact between the user and the mobile terminal 100 in operation 203, the control unit 160, in operation 205, activates the acceleration sensor and controls it to sense movement of the mobile terminal 100. Here, the acceleration sensor may be any sensor that can sense movement of an entity. The acceleration sensor may be installed inside or outside of the housing of the mobile terminal 100.

In operation 207, the control unit 160 checks whether the front of the mobile terminal 100 faces the ground. Here, the movement of the mobile terminal 100 is continuously sensed to precisely time this checking. That is, when the sensed movement is zero, whether the front faces the ground is checked. Although the movement value of zero is preferable, a threshold value regarded as substantially the movement value of zero may be set provided that the mobile terminal 100 does not malfunction.

When the movement value is zero and the front of the mobile terminal 100 does not face the ground, the control unit 160, in operation 209, checks the presence of a second speaker having a gain different from that of the first speaker currently outputting sound. Here, the second speaker (if present) is assumed to have a higher gain than the first speaker.

If a second speaker having a higher gain than the first speaker is not present, the control unit 160, in operation 211, transitions from the regular conversation mode to the speakerphone mode by raising the gain of the first speaker and raising the microphone gain. If a second speaker having a higher gain than the first speaker is present, the control unit 160, in operation 213, transitions from the regular conversation mode to the speakerphone mode by changing the sound output path toward the second speaker and raising the microphone gain.

In the speakerphone mode, when the mobile terminal 100 is shaken in a specific orientation, angle and period, it may transition to the regular conversation mode. Movements other than shaking to control mobile terminal 100 functions may be ignored during the speakerphone mode. For example, if the front of the mobile terminal 100 is placed to face the ground after entering the speakerphone mode, sensing signals indicating movements other than shaking may be ignored so that the speakerphone mode may be sustained.

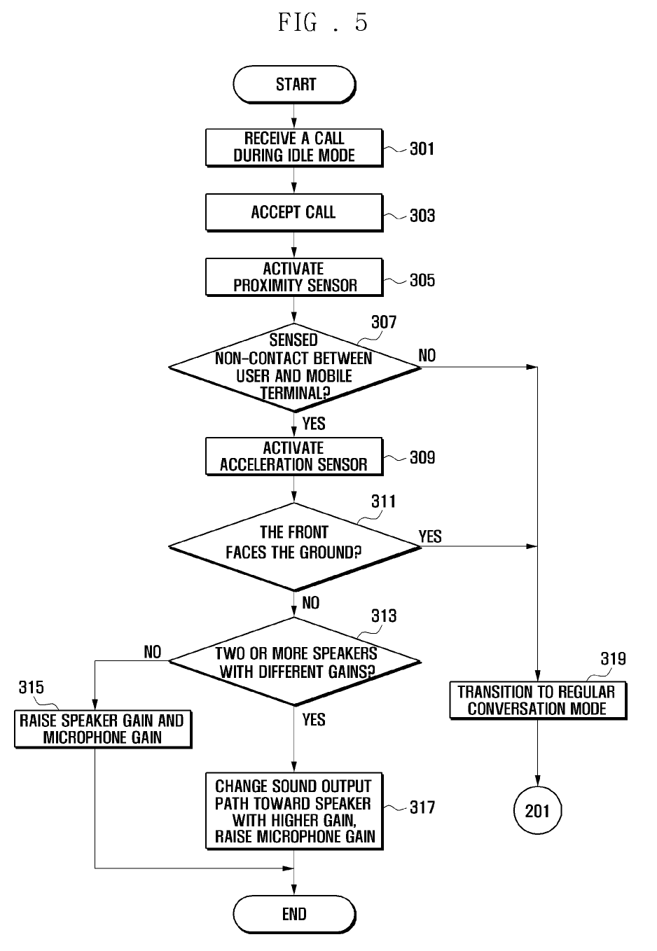

Next, in connection with FIG. 5, a description is given of a procedure for transitioning from the idle mode to the regular conversation mode or to the speakerphone mode depending upon preset conditions for reception of a call. Here, the regular conversation mode and the speakerphone mode are described in connection with FIG. 4.

Referring to FIG. 5, in operation 301, when the mobile terminal 100 in the idle mode receives a call from a serving base station, the user requests the mobile terminal 100, in operation 303, to accept the call. These steps are performed according to a normal call handling procedure.

After accepting the call, the control unit 160, in operation 305, controls the proximity sensor to sense the proximity of the user to the mobile terminal 100. Here, the proximity sensor may be any sensor that can sense contact or non-contact. The proximity sensor may be installed near the speaker SPK or at the display unit 140 so that it can be brought into contact with the ear or the face during a call.

In operation 307, when the proximity sensor senses non-contact between the user and the mobile terminal 100, the control unit 160, in operation 309, activates the acceleration sensor and controls it to sense movement of the mobile terminal 100. Here, the acceleration sensor may be any sensor that can sense movement of an entity. The acceleration sensor may be installed inside or outside of the housing of the mobile terminal 100.

In operation 311, the control unit 160 checks whether the front of the mobile terminal 100 faces the ground on the basis of a sensing signal from the acceleration sensor. Here, the movement of the mobile terminal 100 is continuously sensed to precisely time this checking. That is, when the sensed movement is zero, whether the front faces the ground is checked. Although the movement value of zero is preferable, a threshold value regarded as substantially the movement value of zero may be set provided that the mobile terminal 100 does not malfunction.

When the movement value is zero and the front of the mobile terminal 100 does not face the ground, the control unit 160, in operation 313, checks whether two or more speakers with different gains are present. Here, it may be assumed that a first speaker is used for normal phone conversation, and a second speaker (if present) has a higher gain than the first speaker.

If the first speaker is the only speaker, the control unit 160, in operation 315, transitions to the speakerphone mode by raising the gain of the first speaker and raising the microphone MIC gain. If a second speaker having a higher gain than the first speaker is present, the control unit 160, in operation 317, transitions to the speakerphone mode by changing the sound output path toward the second speaker and raising the microphone MIC gain.

When the mobile terminal contacts the user, or the mobile terminal does not contact the user and the front of the mobile terminal faces the ground, the control unit 160, in operation 319, transitions to the regular conversation mode by adjusting the gain of the first speaker (regardless of the number of speakers) and adjusting the gain of the microphone MIC for the regular conversation mode. During the regular conversation mode, the mobile terminal 100 may operate according to the procedure of FIG. 4.

Although the procedures of FIGS. 4 and 5 depict that both the speaker gain and microphone gain are raised for the speakerphone mode, the speaker gain alone may be adjusted without changing the microphone gain to prevent feedback between the speaker SKP and microphone MIC.

In the speakerphone mode, when the mobile terminal 100 is shaken in a specific orientation, angle and period, it transitions to the regular conversation mode. Movements other than shaking for mode transition may be ignored in the speakerphone mode. For example, if the front of the mobile terminal is placed to face the ground after entering the speakerphone mode, sensing signals indicating movements other than shaking may be ignored so that the speakerphone mode may be sustained.

In an exemplary embodiment, sensing of the proximity of the user to the mobile terminal 100 and sensing of the housing orientation of the mobile terminal 100 may be used to control not only the speaker SPK and microphone MIC but also turning on and off of the display unit 140. For example, the display unit 140 may be turned off during the regular conversation mode, and may be turned on during the speakerphone mode to enable the user to, for example, compose a memo or short text message (a multitasking feature).

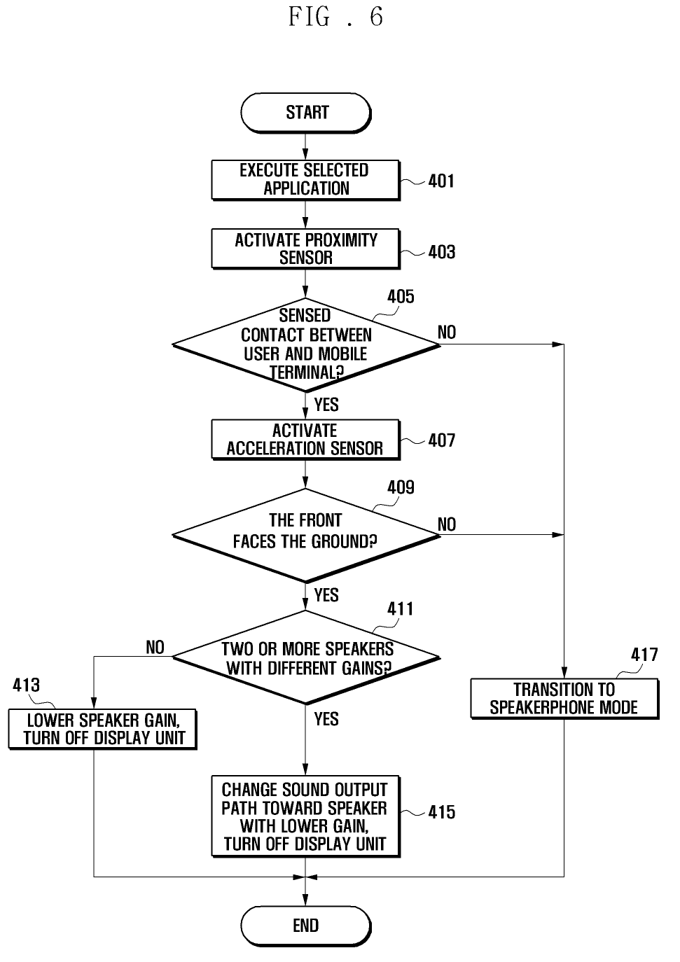

Next, in connection with FIG. 6, a description is given of a procedure for the mobile terminal 100 to control the speaker SPK during execution of an application such as, for example, multimedia playback or DMB reception. Here, it is assumed that when an application such as a multimedia player or a DMB receiver is executed, the sound is output through a speaker having a high gain and the display unit 140 is turned on.

Referring to FIG. 6, in operation 401, when an application such as a multimedia player or a DMB receiver is executed in the mobile terminal, 100 the control unit 160, in operation 403, controls a proximity sensor to sense the proximity of the user to the mobile terminal 100. Here, the proximity sensor may be any sensor that can sense contact or non-contact. The proximity sensor may be installed near the speaker SPK or at the display unit 140 so that it can be brought into contact with the ear or the face during a call.

In operation 405, when the proximity sensor senses contact between the user and the mobile terminal 100, the control unit 160, in operation 407, activates the acceleration sensor and controls it to sense movement of the mobile terminal 100. Here, the acceleration sensor may be any sensor that can sense movement of an entity. The acceleration sensor may be installed inside or outside of the housing of the mobile terminal 100.

In operation 409, the control unit 160 checks whether the front of the mobile terminal 100 faces the ground on the basis of a sensing signal from the acceleration sensor. Here, the movement of the mobile terminal 100 is continuously sensed to precisely time this checking. That is, when the sensed movement is zero, whether the front faces the ground is checked. Although the movement value of zero is preferable, a threshold value regarded as substantially the movement value of zero may be set provided that the mobile terminal 100 does not malfunction.

When the movement value is zero and the front of the mobile terminal 100 does face the ground, the control unit 160, in operation 411, checks whether two or more speakers with different gains are present. Here, it may be assumed that a first speaker is used for normal phone conversation, and a second speaker (if present) has a higher gain than the first speaker. Normally, during execution of the application such as a multimedia player or a DMB receiver, the second speaker and display unit 140 are turned on, and the microphone MIC is turned off or a signal input to the microphone MIC is ignored.

If the first speaker is the only speaker, the control unit 160, in operation 413, lowers the gain of the first speaker and turns off the display unit 140. If a second speaker having a higher gain than the first speaker is present, the control unit 140, in operation 415, changes the sound output path toward the first speaker and turns off the display unit 140. In other words, when the mobile terminal 100, executing an application, remains in contact with the user without movement and the front thereof faces the ground, it is regarded that the user in contact with the mobile terminal 100 is unable to view the display unit 140. Hence, the speaker output is provided and the display unit 140 is turned off, reducing unnecessary power consumption.

When the mobile terminal 100 does not contact the user, or the mobile terminal 100 contacts the user and the front thereof does not face the ground, the control unit 160, in operation 417, raises the speaker volume to a level suitable for the application (regardless of the number of speakers) and turns on the display unit 140.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An operating mode control apparatus for a mobile terminal, comprising:
a sensor unit to sense a proximity of a user to the mobile terminal, to sense a housing orientation of the mobile terminal, and to output a sensing signal that indicates at least one of the proximity and the housing orientation;
a storage unit to store operating mode information of the mobile terminal corresponding to the sensing signal from the sensor unit; and
a control unit to receive the sensing signal and to control an operating mode of the mobile terminal on the basis of the operating mode information corresponding to the received sensing signal.

2. The operating mode control apparatus of claim 1, wherein the housing orientation is determined based on a side of the mobile terminal comprising a display unit.

3. The operating mode control apparatus of claim 1, wherein the sensor unit comprises at least one of:
a first sensor unit to sense contact between the user and the mobile terminal; and
a second sensor unit to sense the housing orientation of the mobile terminal.

4. The operating mode control apparatus of claim 3, wherein the second sensor unit is configured to sense the housing orientation of the mobile terminal after the first sensor unit senses no contact between the user and the mobile terminal.

5. The operating mode control apparatus of claim 3, wherein the sensor unit comprises a sensor to sense movement of the mobile terminal.

6. The operating mode control apparatus of claim 5, wherein the control unit comprises:
a sensing recognizer to determine the proximity of the user to the mobile terminal, and to identify the movement and the housing orientation of the mobile terminal, on the basis of the sensing signal from the sensor unit; and
an operation adjuster to control the operating mode of the mobile terminal according to a result produced by the sensing recognizer.

7. The operating mode control apparatus of claim 6, wherein the control unit controls the operation of at least one of a speaker, a microphone and a display unit of the mobile terminal.

8. The operating mode control apparatus of claim 7, wherein:
to transition between modes where a single speaker is present in the mobile terminal, the control unit adjusts the gain of the single speaker; and,
to transition between modes where two or more speakers are present in the mobile terminal, the control unit alters a sound output path leading to the speakers.

9. An operating mode control method for a mobile terminal, comprising:
sensing a proximity of a user to the mobile terminal, and sensing a housing orientation of the mobile terminal; and
controlling an operating mode of the mobile terminal on the basis of a sensing signal and operating mode information corresponding to the sensing signal, the sensing signal indicating at least one of the proximity and the housing orientation.

10. The operating mode control method of claim 9, wherein the housing orientation is determined based on a side of the mobile terminal comprising a display unit.

11. The operating mode control method of claim 9, wherein sensing the housing orientation of the mobile terminal takes place after sensing that the user is not in proximity to the mobile terminal.

12. The operating mode control method of claim 9, further comprising sensing a movement of the mobile terminal.

13. The operating mode control method of claim 12, wherein controlling the operating mode comprises:
determining the proximity of the user to the mobile terminal;
identifying the movement or the housing orientation of the mobile terminal; and
controlling the operating mode of the mobile terminal according to the determination and identification results.

14. The operating mode control method of claim 13, wherein controlling the operating mode comprises controlling the operation of at least one of a speaker, a microphone and a display unit of the mobile terminal.

15. The operating mode control method of claim 14, wherein:
in controlling the operating mode to transition between modes, where a single speaker is present in the mobile terminal, the gain of the single speaker is adjusted; and
in controlling the operating mode to transition between modes, where two or more speakers are present in the mobile terminal, a sound output path leading to the speakers is altered.
